(19) United States
(12) Patent Application Publication
(10) Pub. No.: US 2007/0184626 A1
(43) Pub. Date: Aug. 9, 2007

(54) METHOD OF MANUFACTURING FERROELECTRIC CAPACITOR AND METHOD OF MANUFACTURING SEMICONDUCTOR MEMORY DEVICE

(75) Inventor: Toshihiko KAMATANI, Tokyo (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 11/564,839

(22) Filed: Nov. 29, 2006

(30) Foreign Application Priority Data
Feb. 9, 2006 (JP) 2006-032542

(51) Int. Cl. H01L 21/20

(52) U.S. Cl. 438/393

(57) ABSTRACT

A method of manufacturing a semiconductor device includes the steps of preparing a substrate having a semiconductor element; forming an insulation film on a surface of the substrate; forming a first film on the insulation film, the first film being a film which does not allow oxygen atoms to pass through; forming a first conductive film on the first film; forming a ferroelectric film on the first conductive film; forming a second conductive film on the ferroelectric film; forming a second film on the second conductive film; patterning the second film into a predetermined shape; forming a ferroelectric capacitor by etching the second conductive film, the ferroelectric film and the first conductive film using the patterned second film as a mask; and etching the exposed first film using mixed gas including a reductive gas.

### BACKGROUND OF THE INVENTION

### Field of the Invention

The present invention relates to a method of manufacturing a ferroelectric capacitor and a method of manufacturing a semiconductor memory device, particularly to those in which a ferroelectric capacitor with a laminated structure made up of an upper electrode, a ferroelectric film and a lower electrode is to be formed by etching continuously.

Conventional ferroelectric capacitors include those which use a ferroelectric material as a capacity insulation film. Nonvolatile memories such as a FeRAM (ferroelectric random-access memory) using this type of ferroelectric capacitor have been given a high degree of expectation as alternatives to a DRAM (dynamic random-access memory), and various types of development on such nonvolatile memories have been carried out.

The ferroelectric material to be used for the capacity insulation film in the ferroelectric capacitor can be a metal compound such as strontium bismuth tantalate (Sr₂Bi₂TaO₉, hereinafter referred to as SBT), lead zirconate titanate (Pb (Zr, Ti) O₃, hereinafter referred to as PZT), or bismuth lanthanum titanate ((Bi, La)₄Ti₃O₁₂, hereinafter referred to as BLT), etc. It is known that such metal compounds would be normally be reduced by highly reductive atoms such as hydrogen (H) and boron (B), etc.

In a method of forming a ferroelectric capacitor according to the conventional technology, normally, a resist pattern with a predetermined shape is used to continuously etch a laminated structure film made up of an upper electrode, a ferroelectric film and a lower electrode. One example of such conventional method is shown in Japanese Laid Open Patent Application No. 5-29901 or Japanese Laid Open Patent Application No. 2000-173999 (patent reference 1). In the following, the structure of the ferroelectric capacitor formed by such method will be called a stack structure. Moreover, the above-mentioned continuous etching conducted within the same chamber will be called batch processing.

However, in the method of forming a ferroelectric capacitor by batch-processing the laminated structure film in the above-described way, the ferroelectric film might become damaged by the etching and therefore might be altered. This will lead to a problem of reducing the amount of residual polarization of the ferroelectric film, or a problem of increasing the leak current between the upper electrode and the lower electrode, etc. Such problems may become more prominent particularly as the capacitor structure is miniaturized for the purpose of realizing high integration.

As to a method of resolving such problems, there is one method, for example, in which the lower electrode is patterned in advance, after which a ferroelectric film for the capacity insulation film and a conductive film for the lower electrode are formed sequentially on the patterned lower electrode, and then the ferroelectric film and the conductive film are patterned to form the capacity insulation film and the upper electrode, respectively. In the following, this method will be called conventional technology 1.

With the conventional technology 1, it is possible to secure a more effective capacitor region than in the case of using the stack structure ferroelectric capacitor, and therefore, it is also possible to inhibit a reduction in the amount of residual polarization.

Furthermore, in the method of forming a ferroelectric capacitor by batch-processing the laminated structure film, material-associated conductive products generated at the time of etching the lower electrode may adhere to the side faces of the ferroelectric film, which leads to a problem of causing an inter-electrode short circuit via the adhered conductive products.

As to a method of resolving such problem, there is one method, for instance, in which the upper electrode and the ferroelectric film are patterned, after which the side faces of the patterned upper electrode and the ferroelectric film are covered by a protective film such as a silicon oxide film having good insulation qualities, and then the lower electrode is patterned. In the following, this method will be called conventional technology 2.

With the conventional technology 2, the side faces of the ferroelectric film will not be exposed at the time of patterning the lower electrode, and therefore, it is possible to prevent possible conductive products generated at the time of patterning the lower electrode from adhering to the side faces of the ferroelectric film. As a result, it will be possible to prevent a possible inter-electrode short circuit between the upper electrode and the lower electrode.

With respect to the conventional technology 1, however, the patterning of the lower electrode and the patterning of the upper electrode and the ferroelectric film are done in separate processes, leading to a problem of making the overall manufacturing processes complicated. Moreover, with respect to the conventional technology 1, different photo-masks are needed in patterning the lower electrode and patterning the upper electrode and the ferroelectric film, leading to a problem of increasing manufacturing costs.

In the meantime, with respect to the conventional technology 2, after the upper electrode and the ferroelectric film are patterned, it is necessary to conduct an additional process of forming an insulation film for covering the side faces of the upper electrode and ferroelectric film, leading to a problem of making the overall manufacturing processes complicated.

In view of the above, it will be apparent to those skilled in the art from this disclosure that there exists a need for an improved method of manufacturing a ferroelectric capacitor and an improved method of manufacturing a semiconductor memory device. This invention addresses this need in the art as well as other needs, which will become apparent to those skilled in the art from this disclosure.

### SUMMARY OF THE INVENTION

It is therefore an object of the present invention to resolve the above-described problems, and to provide a method of manufacturing a ferroelectric capacitor and a method of manufacturing a semiconductor memory device which are capable of reducing leak current between upper electrode and lower electrode, and forming the ferroelectric capacitor by batch processing.

In accordance with one aspect of the present invention, a method of manufacturing a ferroelectric capacitor comprises the steps of: preparing a substrate having an insulation film formed on a surface of the substrate; forming a first film on the insulation film, the first film being a film which does not allow oxygen atoms to pass therethrough; forming a first conductive film on the first film; forming a ferroelectric film on the first conductive film; forming a second conductive film on the ferroelectric film; forming a second film on the second conductive film; patterning the second film into a predetermined shape; forming a ferroelectric capacitor by etching the second conductive film, the ferroelectric film and the first conductive film while using the patterned second film as a mask; and etching the exposed first film using gas including a reductive gas.

In accordance with another aspect of the present invention, a method of manufacturing a semiconductor device comprises the steps of: preparing a substrate having a semiconductor element; forming an insulation film on a surface of the substrate; forming a first film on the insulation film, the first film being a film which does not allow oxygen atoms to pass therethrough; forming a first conductive film on the first film; forming a ferroelectric film on the first conductive film; forming a second conductive film on the ferroelectric film; forming a second film on the second conductive film; patterning the second film into a predetermined shape; forming a ferroelectric capacitor by etching the second conductive film, the ferroelectric film and the first conductive film using the patterned second film as a mask; and etching the exposed first film using mixed gas including a reductive gas.

These and other objects, features, aspects, and advantages of the present invention will become apparent to those skilled in the art from the following detailed description, which, taken in conjunction with the annexed drawings, discloses preferred embodiments of the present invention.

### BRIEF DESCRIPTION OF THE DRAWINGS

Referring now to the attached drawings which form a part of this original disclosure:

FIG. 1 is a diagram showing a sectional structure of a nonvolatile memory according to one embodiment of the present invention;

FIGS. 2A-2B, 3A-3B, 4A-4B and 5A-5B are diagrams showing steps in the process of manufacturing a semiconductor memory device according to one embodiment of the present invention;

FIG. 6 is a graph showing the hysterisis characteristics of a ferroelectric film in different situations; and

FIG. 7 is a diagram showing a step in the process of manufacturing a semiconductor memory device according to one embodiment of the present invention.

### DETAILED DESCRIPTION OF THE PREFERRED EMBODIMENTS

Selected embodiments of the present invention will now be explained with reference to the drawings. It will be apparent to those skilled in the art from this disclosure that the following descriptions of the embodiments of the present invention are provided for illustration only and not for the purpose of limiting the invention as defined by the appended claims and their equivalents.

In the following, the structure shown in each drawing is shown in certain shape, size and position in a way simple enough to show the outline of the present invention. Therefore, the shape, size and position of the present invention are not limited to the ones shown in the drawings. In addition, in each drawing, in order to clearly show the structure, a portion of the hatching in a cross-sectional surface is omitted. Moreover, numerical values indicated in the following description are only given as examples, and therefore, they are not in the nature of limiting the present invention.

In the following, one embodiment of the present invention will be described in detail with reference to the drawings. In this embodiment, a nonvolatile memory as a semiconductor memory device according to the present invention will be described, the nonvolatile memory including a ferroelectric capacitor having a stack structure.

### Structure

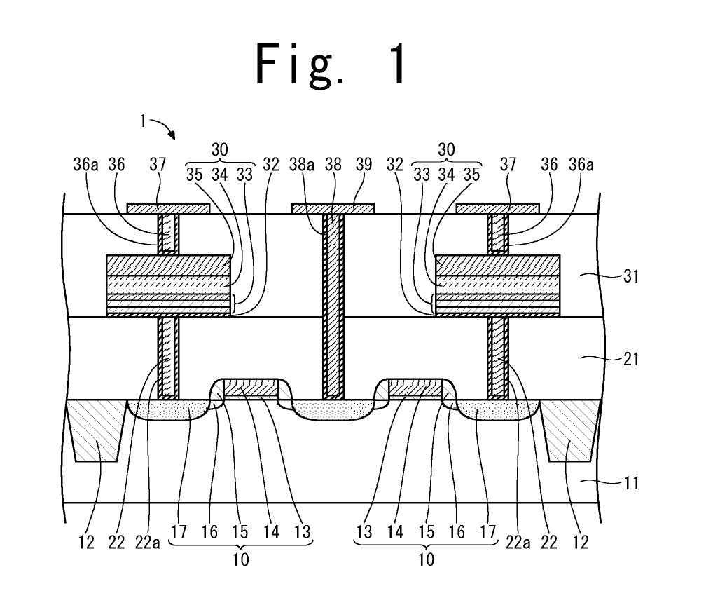

FIG. 1 is a diagram showing a sectional structure of a nonvolatile memory 1 according to one embodiment of the present invention. As shown in FIG. 1, the nonvolatile memory 1 has a semiconductor substrate 11, transistors 10 formed on the semiconductor substrate 11, a first interlayer insulation film 21 formed on the semiconductor substrate 11, ferroelectric capacitors 30 formed on the first interlayer insulation film 21, a second interlayer insulation film 31 formed on the first interlayer insulation film 21, metal wirings 37 and 39 formed on the second interlayer insulation film 31, and contact plugs 22, 36 and 38 serving to electrically connect between layers.

In the above structure, the semiconductor substrate 11 is a silicon substrate including p type impurities, for instance, and having substrate resistance of about 8 to 22 Ω (ohm), for instance. However, this is not a limiting condition for the semiconductor substrate 11, and all other types of semiconductor substrates may be possible options for the semiconductor substrate 11.

On the surface of the semiconductor substrate 11, element separating insulation films 12 are formed using the STI (shallow trench isolation) method or LOCOS (local oxidation of silicon) method, etc., for instance. Thereby, multiple element forming regions are defined on the surface of the semiconductor substrate 11.

In the element formation regions in the semiconductor substrate 11, semiconductor elements such as transistors, for instance, are formed. This embodiment will be one in which a transistor 10 is formed in each of two element forming regions. Each transistor 10 includes a gate insulation film 13 and a gate electrode 14 both formed on the semiconductor substrate 11, sidewalls 15 formed on the side faces of the gate electrode 14, lightly doped drains (hereinafter referred to as LDDs) 16 formed on the surface of the semiconductor substrate 11 underneath the sidewalls 15, respectively, and highly doped regions 17 formed on the surface of the semiconductor substrate 11 so as to sandwich the LDDs 16 therebetween.

Here, the first interlayer insulation film 21 is formed on the semiconductor substrate 11 having the semiconductor elements including the transistors 10 formed thereon in the above-described way, and such that it will have enough thickness to bury the semiconductor elements. As for the first interlayer insulation film 21, it is possible to use a silicon oxide film, for instance, or all other types of insulation films which have conventionally been used as interlayer insulation films (also called intermediate insulation films).

The ferroelectric capacitors 30 are formed on the first interlayer insulation film 21, for instance. Each ferroelectric capacitor 30 includes a lower electrode 33, a capacity insulation film 34 and an upper electrode 35.

As for the lower electrode 33 in the ferroelectric capacitor 30, it is possible to use a laminated structured conductive film including an iridium (Ir) film (equivalent to an Ir film 33a to be described later on) in the lowest layer, an iridium oxide (IrO₂) film (equivalent to an IrO₂ film 33b to be described later on) formed on the Ir film, and a platinum (Pt) film (equivalent to a Pt film 33c to be described later on) formed on the IrO₂ film, for instance. The thickness of the Ir film may be about 500 to 1000 Å, for instance, the thickness of the IrO₂ may be about 500 to 1000 Å, for instance, and the thickness of the Pt film may be about 500 to 1000 Å, for instance.

As for the capacity insulation film 34 in the ferroelectric capacitor 30, it is possible to use all types of ferroelectric films such as SPT, PZT, BLT, etc., for instance. The thickness of the capacity insulation film 34 may be about 1200 Å, for instance.

As for the upper electrode 35 in the ferroelectric capacitor 30, it is possible to use a Pt film, and it may be about 1000 to 1500 Å thick, for instance.

In this embodiment, the ferroelectric capacitor 30 may be covered with a barrier film which is capable of preventing highly reductive atoms such as hydrogen (H) and boron (B), etc., from diffusing.

In between the lower electrode 33 and the first interlayer insulation film 21, a diffusion prevention film 32 is formed as a layer for preventing the lower electrode 33 from being oxidized due to oxygen atoms diffusing from the first interlayer insulation film 21 to the lower electrode. Accordingly, through this diffusion prevention film 32, the lower electrode 33 is electrically connected to the contact plug 22 formed in the first interlayer insulation film 21. As for this diffusion prevention film 32, it is possible to use a conductive film such as titanium aluminum nitride (TiAlN) film, etc., for instance, and it may be about 500 to 1000 Å thick, for instance. In the present invention, the diffusion prevention film 32 may be included as a portion of the lower electrode 33.

The second interlayer insulation film 31 is formed on the first interlayer insulation film 21 where the ferroelectric capacitors are formed in the above described way. As for this second interlayer insulation film 31, as with the first interlayer insulation film 21, it is possible to use a silicon oxide film or a silicon nitride film, for instance, or all other types of insulation films which have conventionally been used as interlayer insulation films.

On the second interlayer insulation film 31, the metal wirings 37 electrically connected to the ferroelectric capacitors 30 in the lower layer, and the metal wiring 39 electrically connected to the transistors 10 are formed, for instance. As for the metal wirings 37 and 39, they may be formed to include a first titanium nitride (TiN) film formed in the lowest layer, an aluminum alloy film formed on the TiN film, and a second TiN film formed on the aluminum alloy film, for instance. The first TiN film is a film which makes the aluminum alloy film, which is a principal part of the metal wiring 37 or 39, adhere to the second interlayer insulation film 31. In this respect, all types of conductive films besides the TiN film may also be applied for this purpose. Here, the first TiN film may be about 500 Å thick, for instance.

As mentioned above, the aluminum alloy film is the principal part of the metal wirings 37 and 39. However, it is also possible to apply all types of conductive films besides the aluminum alloy film for this purpose. For instance, it is possible to apply a silicon film including aluminum, copper, impurities, etc., or an alloy film including one or more of these materials. In this respect, however, it is preferable that the conductive film is made of a material which can prevent highly reductive atoms such as hydrogen (H) and boron (B), etc., from diffusing. Here, the aluminum alloy film may be about 500 to 1000 Å thick, for instance.

The second TiN film is a film which makes the aluminum alloy film, which is the principal part of the metal wiring 37 or 39, adhere to a film (e.g., a barrier film functioning to prevent highly reductive atoms from diffusing from the upper layer to the lower layer) formed on the second interlayer insulation film 31. In this respect, all types of conductive films besides the TiN film may also be applied for this purpose. Here, the second TiN film may be about 1000 Å thick, for instance.

In the first and second interlayer insulation films 21 and 31, contact plugs 22, 36 and 38 are formed. The contact plug 22 is a wiring for electrically connecting the transistor 10 and the lower electrode 33 in the ferroelectric capacitor 30, for instance, and it is formed inside a contact hole that is formed in the first interlayer insulation film 21. The contact plug 36 is a wiring for electrically connecting the upper electrode 35 in the ferroelectric capacitor 30 and the metal wiring 37, for instance, and it is formed inside a contact hole that is formed in the second interlayer insulation film 31. The contact plug 38 is a wiring for electrically connecting the transistor 10 and the metal wiring 39, for instance, and it is formed inside a contact hole that is formed in the first and second interlayer insulation films 21 and 31. The contact plugs 22, 36 and 38 can be formed by filling the respective contact holes with predetermined conductive material such as aluminum (Al), copper (Cu) or tungsten (W), etc. Furthermore, adherence layers 22a, 36a and 38a are formed between the contact plug 22 and the first interlayer insulation film 21, between the contact plug 36 and the second interlayer insulation film 31, and between the contact plug 38 and the first and second interlayer insulation films 21 and 31, respectively. As for these adherence layers 22a, 36a and 38a, TiN films may be applied, for instance.

On the second interlayer insulation film 31 where predetermined patterns such as the metal wirings 37 and 39 are formed, a barrier film and passivation film are formed, for instance. The barrier film is a film such as a tantalum oxide (TaOx) film or an alumina (Al₂O₃) film, etc., for instance, which will not allow highly reductive atoms such as hydrogen (H) and boron (B), etc. to pass therethrough. When a tantalum oxide film formed by reactive sputtering is applied as the barrier film, for instance, the thickness of the barrier film may be about 1500 Å, for instance. Whereas when an alumina film formed by the CVD (chemical vapor deposition) method is applied as the barrier film, for instance, the thickness of the barrier film may be about 500 Å, for instance. However, these are not definite conditions for the barrier film. As long as the barrier film has a sufficient thickness that will prevent highly reductive atoms that have diffused from the upper layer passivation film, for instance, to pass therethrough, it may be varied. As for the passivation film, it is possible to apply a silicon nitride film formed by the plasma CVD method, for instance. The thickness of the passivation film may be about 7500 Å, for instance.

### Manufacturing Method

Now, a method of manufacturing the nonvolatile memory 1 according to the embodiment of the present invention will be described in detail with reference to the drawings.

In this manufacturing method, first, a semiconductor substrate 11 in which semiconductor elements including transistors 10 are formed using a conventional method, for instance, will be prepared. Next, using the known CVD method, for instance, a first interlayer insulation film 21, which is a silicon oxide film, will be formed to a thickness of about 8000 Å, for instance. Here, the surface of the first interlayer insulation film 21 will be planarized by applying a CMP (chemical and mechanical polishing) method, for instance.

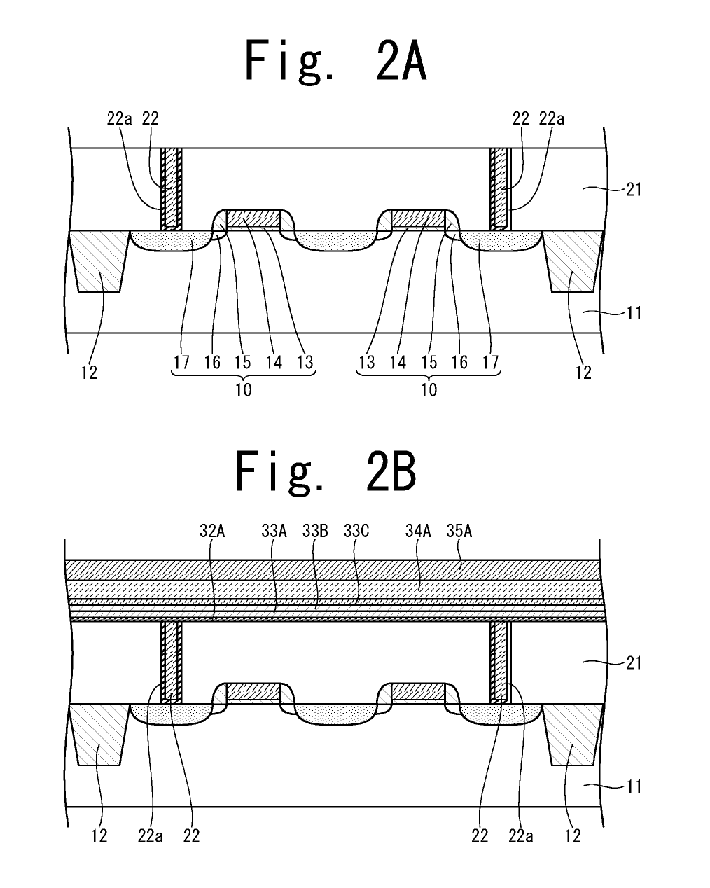

Next, using the known photolithography and etching methods, for instance, contact holes exposing portions of the semiconductor elements having been formed in the semiconductor substrate 11 will be formed in the first interlayer insulation film 21. Then, using a sputtering method, TiN films will be formed on the inner surfaces of the respective contact holes, after which the contact holes will be filled with a predetermined conductive material such as aluminum, copper or tungsten, etc., to form adherence layers 22a and contact plugs 22 in the first interlayer insulation film 21, as shown in FIG. 2A.

Next, using the known sputtering method, for instance, a TiAlN film 32A will be formed to a thickness of about 500 to 1000 Å, for instance, on the first interlayer insulation film 21. In the sputtering process for forming the TIAlN film 32A, TiN (with 1:1 relative proportions) may be used as the target, a mixed gas of N₂ and Ar may be used as the sputtering gas (with a gas flow rate of N₂:Ar being 115:28 sccm, for example), the DC power may be set to about 3000 W (watts), and the deposition temperature may be set to about 200° C., for instance.

Next, using the known sputtering method, for instance, a lower conductive film including an Ir film 33A with a thickness of about 500 to 1000 Å, for instance, an IrO₂ film 33B with a thickness of about 500 to 1000 Å, for instance, and a Pt film 33C with a thickness of about 500 to 1000 Å, for instance, will be formed on the first interlayer insulation film 21. In forming the Ir film 33A, Ir may be used as the target, Ar gas may be used as the intra-chamber atmosphere, the DC power may be set to about 1000 W, and the deposition temperature may be set to about 400° C., for instance. In forming the IrO₂ film 33B, Ir may be used as the target, Ar gas and oxygen (O₂) gas may be used as the intra-chamber atmosphere, the DC power may be set to about 500 W, and the deposition temperature may be set to about 350° C., for instance. In forming the Pt film 33C, Pt may be used as the target, Ar gas may be used as the intra-chamber atmosphere, the DC power may be set to about 1000 W, and the deposition temperature may be set to about 200° C., for instance.

Next, using the known sol-gel method, for instance, a ferroelectric film 34A will be formed to a thickness of about 1200 Å, for instance, on the Pt film 33C of the lower conductive film. In this embodiment, the ferroelectric film 34A is an SBT (strontium bismuth tantalate (SrBi₂Ta₂O₉)) film, for instance. This SBT film can be formed by a three-layer coating sol-gel method, for instance. To be more precise, first, a precursor solution, in which SBT is dissolved, is spin-coated, for the first time, on the lower conductive film, after which crystallization annealing is conducted at a temperature of 700° C. to form a first layer SBT film. Then, the same precursor solution will be spin-coated, for the second time, on the first layer SBT film, after which crystallization annealing is conducted at a temperature of 700° C. to form a second layer SBT film. Then, the same precursor solution will be spin-coated, for the third time, on the second layer SBT film, after which crystallization annealing is conducted at a temperature of 800° C. to form a third layer SBT film. Thus, the ferroelectric film 34A can be formed. In this respect, however, it is also possible to use all other methods, such as the CVD method, for instance.

Next, using the known sputtering method, for instance, an upper conductive film 35A made of Pt will be formed to a thickness of about 1000 to 1500 Å, for instance, on the ferroelectric film 34A. Thus, as shown in FIG. 2B, a laminated structure film including the TiAlN film 32A, the lower conductive film made of the Ir film 33A, IrO2 film 33B and Pt film 33C, the ferroelectric film 34A, and the upper conductive film 35A will be formed on the first interlayer insulation film 21. Here, in forming the Pt film (i.e., the upper conductive film 35A), Pt may be used as the target, Ar gas may be used as the intra-chamber atmosphere, the DC power may be set to about 1000 W, and the deposition temperature may be set to about 200° C., for instance, as with the case of forming the Pt film 33C of the lower conductive film.

Next, using the known sputtering method, for instance, a TiN film 33D will be formed to a thickness of about 1000 Å, for instance, on the upper conductive film 35A. This TiN film 33D is to be processed into a hard mask to be used in patterning a lower electrode 33 and a diffusion prevention film 32 in a later process. Accordingly, the TiN film 33D does not necessarily have to be 1000 Å thick as just mentioned. The TiN film 33D should have an appropriate thickness which will prevent it from disappearing by the end of patterning of the lower electrode 33, but allow it to disappear by the end of patterning of the diffusion prevention film 32. In forming the TiN film 33D, Ti may be used as the target, N₂ may be used as the sputtering gas (with a gas flow rate of N₂ being 79 sccm, for example), the DC power may be set to about 5000 W, and the deposition temperature may be set to about 100° C., for instance.

Next, using the known CVD method, for instance, a silicon oxide film 34B will be formed to a thickness of about 4000 Å, for instance, on the TiN film 33D. This silicon oxide film 34B is to be processed into a hard mask to be used in patterning a capacity insulation film 34 in a later process. Accordingly, the silicon oxide film 34B does not necessarily have to be 4000 Å thick as just mentioned. The silicon oxide film 34B should have an appropriate thickness which will prevent it from disappearing by the time patterning of the capacity insulation film 34 ends. In forming the silicon oxide film 34B, a P-TEOS (plasma tetraethoxysilane) CVD method may be used, for instance. In this P-TEOS CVD method for forming the silicon oxide film 34B, a mixed gas of TEOS, O₂ and Ar may be used as the source gas (with a gas flow rate of TEOS:O₂:Ar being 115:960:100 sccm, for example), the RF power may be set to two frequencies of about 450 kW and about 240 kW, and the deposition temperature may be set to about 420° C., for instance.

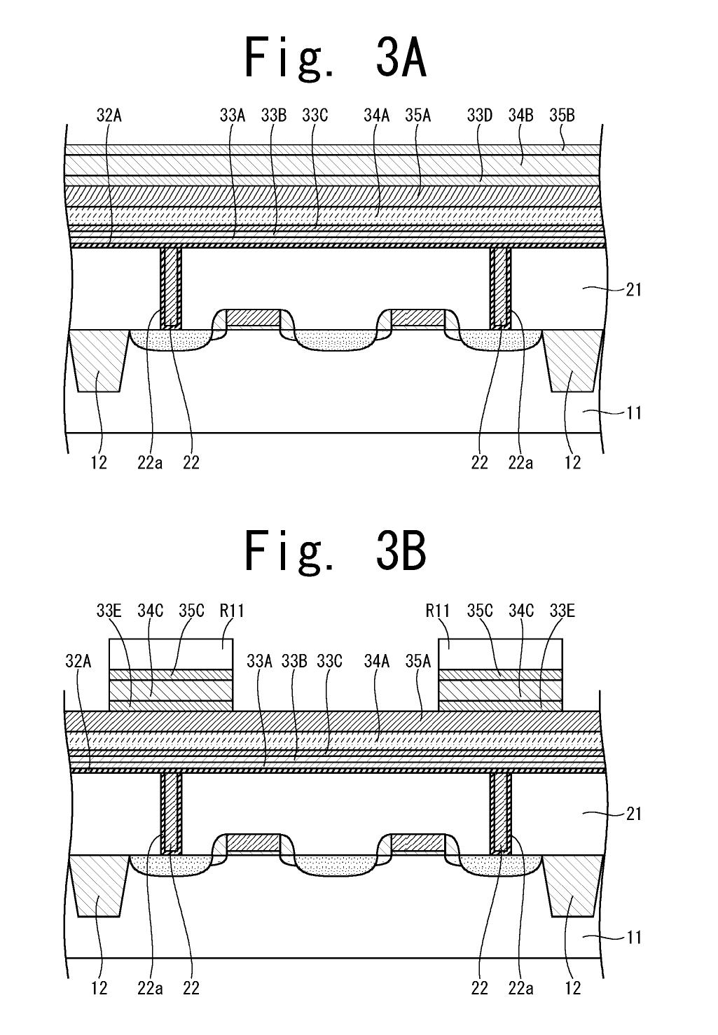

Next, using the known sputtering method, for instance, a TiN film 35B will be formed to a thickness of about 1000 Å, for instance, on the silicon oxide film 34B. This TiN film 35B is to be processed into a hard mask to be used in patterning an upper electrode 35 in a later process. Accordingly, the TiN film 35B does not necessarily have to be 1000 Å thick as just mentioned. The TiN film 35B should have an appropriate thickness which will allow it to disappear by the time patterning of the upper electrode 35 ends, or more preferably, it should have a thickness which will allow it to disappear at the same time as the patterning of the upper electrode 35 ends. Thus, as shown in FIG. 3A, the TiN film 33D, the silicon oxide film 34B, and the TiN film 35B, which will all be processed into hard masks in the later process, will be formed on the upper conductive film 35A. In forming the TiN film 35B, Ti may be used as the target, N₂ may be used as the sputtering gas (with a gas flow rate of N₂ being 79 sccm, for example), the DC power may be set to about 5000 W, and the deposition temperature may be set to about 100° C., for instance.

Next, using the known photolithography method, for instance, a resist pattern R11 on which the upper surface shapes of the ferroelectric capacitors 30 are transcribed will be formed on the TiN film 35B. Then using this resist pattern R11 as a mask, the TiN film 35B, the silicon oxide film 34B and the TiN film 33D will be etched sequentially, to form hard masks, each of which made up of a TiN film 35C, a silicon oxide film 34C and a TiN film 33E, on the upper conductive film 35A, as shown in FIG. 3B. The TiN film 35C will function as a hard mask in forming the upper electrode 35 by etching the upper conductive film 35A. The silicon oxide film 34C will function as a hard mask in forming the capacity insulation film 34 by etching the ferroelectric film 34A. The TiN film 33E will function as a hard mask in forming the lower electrode 33 and the diffusion prevention film 32 by sequentially etching the lower conductive film made up of the Ir film 33A, the IrO₂ film 33B and the Pt film 33C, and the TiAlN film 32A. In etching the TiN films 33D and 35B, a typical dry etching method, which uses a mixed gas of BCl₃ and Cl₂ as the etching gas (with a gas flow rate of BCl₃:Cl₂ being 30:70 sccm, for example) under a gas pressure of about 7.5 mTorr and an RF power of about 60 W, for instance, may be applied. In etching the silicon oxide film 34B, a typical dry etching method, which uses a mixed gas of C₄F₈, CO and Ar as the etching gas (with a gas flow rate of C₄F₈:CO:Ar being 18:300:400 sccm, for example) under a gas pressure of about 55 mTorr and an RF power of about 1300 W, for instance, may be applied. In this respect, however, these etching processes are not limited to the ones mentioned above, and it is also possible to apply a typical etching method which uses an organic release agent, for instance.

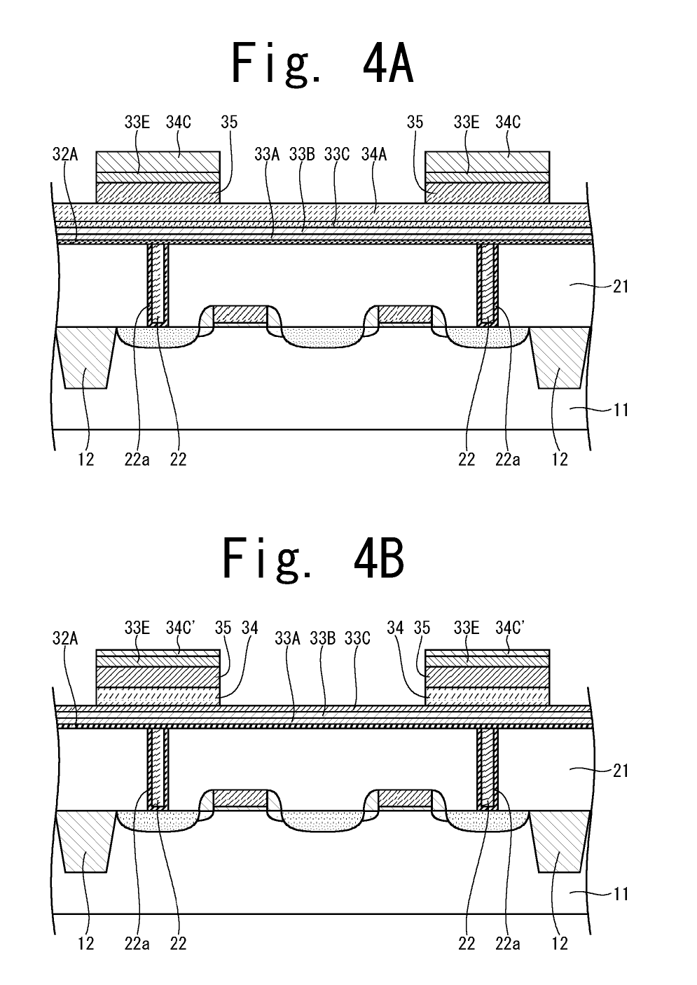

Next, the resist pattern R11 will be removed, and after that, the upper conductive film 35A will be etched while using the TiN film 35C in each hard mask as a mask, by which the upper conductive film 35A will be patterned into upper electrodes 35 as shown in FIG. 4A. In this process, as mentioned earlier, the TiN film 35C is supposed to disappear by the time the patterning of the upper electrode 35 ends. In patterning the upper electrode 35, it is possible to apply parallel plate RIE (i.e., reactive ion etching), in which a mixed gas of Cl₂, Ar and O₂ may be used as the etching gas (with a gas flow rate of Cl₂:Ar:O₂ being 5:10:15 sccm, for example), the gas pressure may be set to about 2 mTorr, the high frequency power to be applied to an intra-chamber upper electrode may be set to 13.56 MHz (megahertz) while its RF power is set to about 1000 W, the high frequency power to be applied to an intra-chamber lower electrode may be set to 450 MHz while its RF power is set to 100 W, and the stage temperature may be set to 450° C., for instance.

Next, the ferroelectric film 34A will be etched while using the silicon oxide film 34C in each hard mask as a mask, by which the ferroelectric film 34A will be patterned into capacity insulation films 34 as shown in FIG. 4B. In this process, as mentioned earlier, the silicon oxide film 34C is not supposed to disappear by the time the patterning of the capacity insulation film 34 ends. Accordingly, in this process, the silicon oxide film 34C on the TiN film 33E will be removed completely by over-etching. In this over-etching, however, it will be controlled such that the TiN film 33E will not be etched more than necessary. In patterning the ferroelectric film 34A, it is possible to apply parallel plate RIE, in which a mixed gas of Cl₂ and Ar may be used as the etching gas (with a gas flow rate of Cl₂:Ar being 10:10 sccm, for example), the gas pressure may be set to about 1 mTorr, the high frequency power to be applied to an intra-chamber upper electrode may be set to 13.56 MHz while its RF power is set to 550 W, the high frequency power to be applied to an intra-chamber lower electrode may be set to 450 MHz while its RF power is set to 120 W, and the stage temperature may be set to 80° C., for instance.

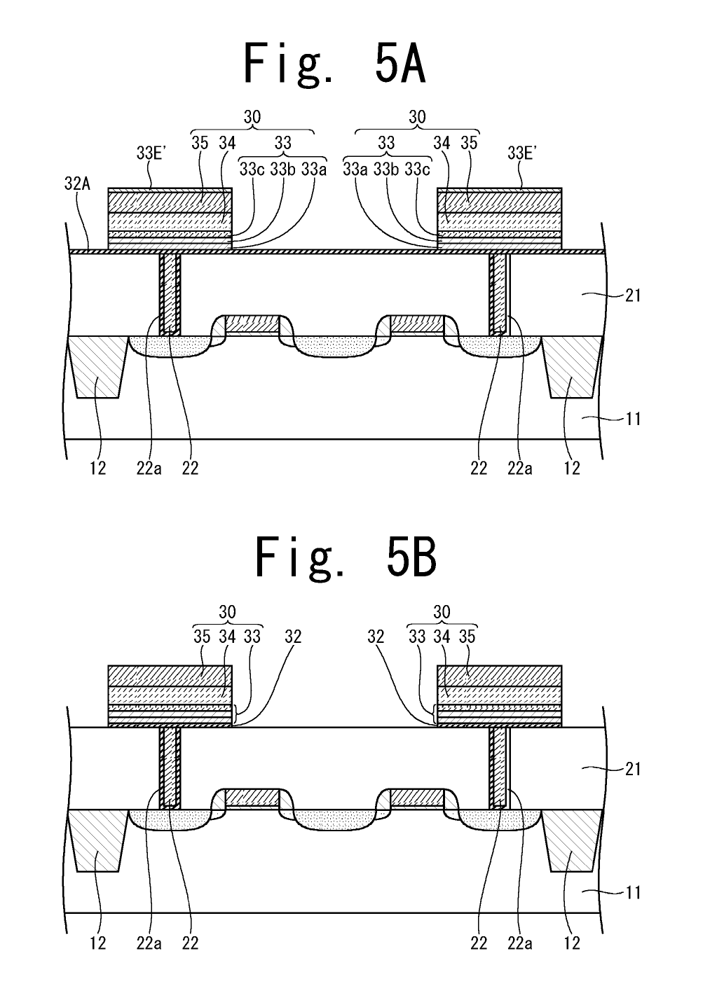

Next, the lower conductive film made up of the Ir film 33A, the IrO₂ film 33B and the Pt film 33C will be etched sequentially while using the TiN film 33E in each hard mask as a mask, by which the Ir film 33A will be patterned into Ir films 33a, the IrO₂ film 33B will be patterned into IrO₂ films 33b and the Pt film 33C will be patterned into Pt films 33c, respectively. Thus, ferroelectric capacitors 30, each of which are made up of a lower electrode 33 including the Ir film 33a, the IrO₂ film 33b and the Pt film 33c, the capacity insulation film 34, and the upper electrode 35, will be formed as shown in FIG. 5A. In this process, as mentioned earlier, the TiN film 33E is not supposed to disappear by the time the patterning of the lower electrode 33 ends. Accordingly, in this process, a thinned TiN film (hereinafter referred to as residual TiN film) 33E′ will remain on each of the upper electrode 35. In patterning the lower conductive film made up of the Ir film 33A, the IrO₂ film 33B and the Pt film 33C, it is possible to apply parallel plate RIE, in which a mixed gas of Cl₂, Ar and O₂ may be used as the etching gas (with a gas flow rate of Cl₂:Ar:O₂ being 5:10:15 sccm, for example), the gas pressure may be set to about 2 mTorr, the high frequency power to be applied to an intra-chamber upper electrode may be set to 13.56 MHz while its RF power is set to about 1000 W, the high frequency power to be applied to an intra-chamber lower electrode may be set to 450 MHz while its RF power is set to 100 W, and the stage temperature may be set to 450° C., for instance.

In this way, in this embodiment, the upper conductive film 35A, the ferroelectric film 34A, and the lower conductive film (33A, 33B and 33C) will be etched continuously, and as a result, stack structure ferroelectric capacitors 30 that are each made up of the upper electrode 35, the capacity insulation film 34 and the lower electrode 33 can be formed.

Regarding the material for forming the electrodes of the ferroelectric capacitors, if thermally and chemically stable conductive material is used, etching efficiency will degrade.

In this embodiment, because the stage temperature in the etching processes is set to a comparatively high temperature of 450° C., a three-layer structured film of TiN film 33E, silicon oxide film 34B and TiN film 35B is used as the hard mask for forming the ferroelectric capacitor. In this regard, however, depending on the component films and film thickness of the ferroelectric capacitor to be formed, it is also possible to apply a two-layer structured film of the silicon oxide film 34B and TiN film 33E, or a single layer structured film of the TiN film 33E as the hard mask. Moreover, it is also possible to use a TiAlN film instead of the TiN film 33E.

After the ferroelectric capacitors 30 are formed in the above-described way, the TIAlN film 32A will be etched while using the residual TiN films 33E′ as masks, by which the TiAlN film 32A will be patterned into diffusion prevention films 32, respectively. Thus, as shown in FIG. 5B, the diffusion prevention film 32 will be formed beneath each lower electrode 33, and the residual TiN film 33E′ on each upper electrode 35 will disappear.

In etching the TiAlN film 32A and the residual TiN film 33E′, it is possible to apply parallel plate RIE, in which a mixed gas having a reductive gas mixed into a halogen gas such as Cl₂ or into a mixed gas of Cl₂ and Ar (with a gas flow rate of Cl₂:Ar being 25:25 sccm, for example) may be used as the etching gas. Here, the reductive gas may be a halide gas such as BCl₃, HBr or CHF₃, etc., for instance, and its gas flow rate may be 25 sccm, for instance.

In this way, by using this kind of mixed gas having a reductive gas mixed thereto as the etching gas, it is possible to raise the volatility of the conductive products adhered to the side faces of the capacity insulation film 34, which is a ferroelectric film, at the time of patterning the lower electrode 33. Accordingly, it is possible to remove the conductive products adhered to the side faces of the capacity insulation film 34 while etching the TIAlN film 32A and the residual TiN film 33E′. As a result, it will be possible to decrease the possible intra-electrode short circuits that can occur between the upper electrode 35 and the lower electrode 33 due to the generated conductive products. In addition, by applying BCl₃ as the gas to be mixed into the etching gas, the selective ratio of the residual TiN film 33E′ and the upper electrode 35 can be improved, and thereby, it will be possible to reduce the amount of scrape in the upper electrode 35 when etching the TiAlN film 32A and the residual TiN film 33E′.

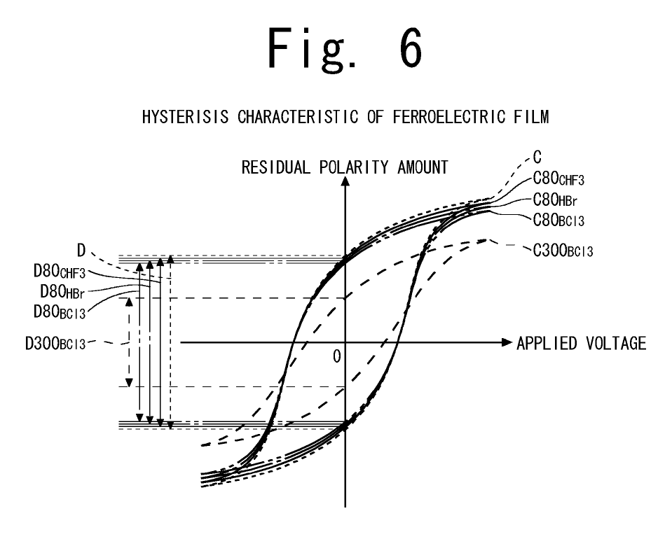

In this respect, however, there is a possibility that the amount of residual polarization might decrease as the capacity insulation film 34, being a ferroelectric film, is exposed to the reductive gas such as BCl₃, HBr or CHF₃, etc. Considering this point, in this embodiment, the temperature at which the ferroelectric film is to be exposed to the reductive gas is set to a comparatively low temperature, such as below 80° C., for instance. By such arrangement, it is possible to restrain the amount of residual polarization in the ferroelectric film from decreasing. FIG. 6 is a graph showing the hysterisis characteristics of the ferroelectric film in different situations. C80_{CHF3} represents the hysterisis characteristics of the ferroelectric film after etching, where a mixed gas of CHF₃ and Ar is used as the etching gas and the stage temperature is set to 80° C. C80_{HBr} represents the hysterisis characteristics of the ferroelectric film after etching, where a mixed gas of HBr and Ar is used as the etching gas and the stage temperature is set to 80° C. C80_{BC13} represents the hysterisis characteristics of the ferroelectric film after etching, where a mixed gas of BCl₃ and Cl₂ is used as the etching gas and the stage temperature is set to 80° C. C300_{BC13} represents the hysterisis characteristics of the ferroelectric film after etching, where a mixed gas of BCl₃ and Cl₂ is used as the etching gas and the stage temperature is set to 300° C. In addition, FIG. 6 also shows the hysterisis characteristics of the ferroelectric film before the ferroelectric film is exposed to the reductive gas.

As shown in FIG. 6, by setting the temperature at which the ferroelectric film is to be exposed to the reductive gas to a comparatively low temperature such as 80° C., it is possible to make the residual polarity amounts D80_{CHF3}, D80_{HBr} and D80_{BC13} of the ferroelectric film after being exposed to the reductive gas approximately the same as the residual polarity amount D of the ferroelectric film before being exposed to the reductive gas. On the other hand, as can be seen from FIG. 6, the residual polarity amount D300_{BC13} of the ferroelectric film when the stage temperature is set to 300° C., for instance, is degraded considerably as compared to the residual polarity amount D of the ferroelectric film before being exposed to the reductive gas. Here, the lower limit of the stage temperature at the time when the ferroelectric film is exposed to the reductive gas may be a normal temperature (e.g., 25° C.), for instance. However, it is appropriate as long as the temperature allows for sufficient etching efficiency to be obtained.

Thus, in this embodiment, after the lower conductive film which is supposed to become the lower electrodes 33 in the ferroelectric capacitors 30 is patterned, etching using a mixed gas including a reductive gas will be conducted. Thereby, in this embodiment, it is possible to raise the volatility of conductive products adhered to the side faces of the capacity insulation films 34 at the time of patterning the lower conductive film. Accordingly, it is possible to remove the conductive products adhered to the side faces of the capacity insulation films 34 while etching the TiAlN film 32A. As a result, even when the upper conductive film 35A, the ferroelectric film 34A and the lower conductive film (33A, 33B and 33C) are etched continuously, i.e., even when these films are batch-processed, it will be possible to decrease possible leak current that can be generated between the upper electrode 35 and the lower electrode 33 in each ferroelectric capacitor 30. Moreover, in this embodiment, the temperature at which the etching using the mixed gas including a reductive gas is set to a comparatively low temperature such as below 30° C., or more preferably below 80° C. By such arrangement, it is possible to restrain the amount of residual polarization in the ferroelectric film (i.e., the capacity insulation film 34) from decreasing due to the reductive gas.

Here, with respect to the other conditions in etching the TiAlN film 32A and the residual TiN film 33E′, the gas pressure may be set to 7.5 mTorr (1 Pa), the high frequency power to be applied to an intra-chamber upper electrode may be set to 13.56 MHz while its RF power is set to about 1200 W, and the high frequency power to be applied to an intra-chamber lower electrode may be set to 450 MHz while its RF power is set to 50 W.

Next, using the known CVD method, for instance, a second interlayer insulation film 31, which is a silicon oxide film, will be formed to a thickness of about 8000 Å, for instance. Here, the surface of the second interlayer insulation film 31 will be planarized by applying a CMP method, for instance.

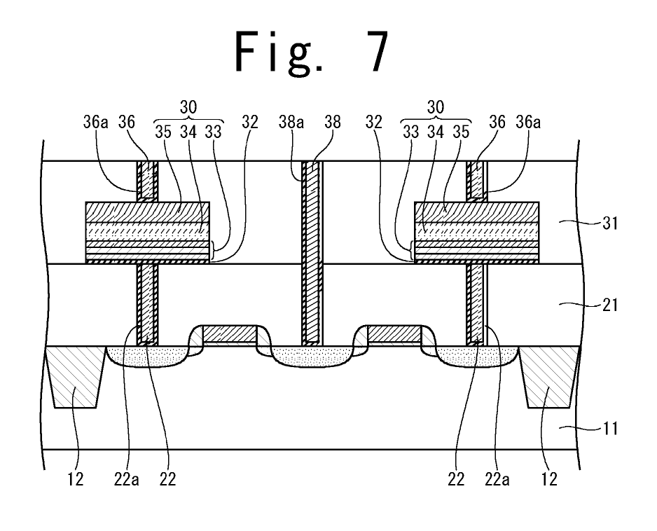

Next, using the known photolithography and etching methods, for instance, contact holes exposing portions of the upper electrodes 35 in the ferroelectric capacitors 30, and a portion of the semiconductor element having been formed in the semiconductor substrate 11, will be formed in the respective first and second interlayer insulation films 21 and 31. Then, using a sputtering method, TiN films will be formed on the inner surfaces of the respective contact holes, after which the contact holes will be filled with a predetermined conductive material such as aluminum, copper or tungsten, etc., to form adherence layers 36a and 38a, and contact plugs 36 and 38, in the respective first and second interlayer insulation films 21 and 31, as shown in FIG. 7.

Next, using the known sputtering method, for instance, a conductive film made up of a TiN film, an Al alloy film and a TiN film, for instance, will be formed on the second interlayer insulation film 31. Then, using the known photolithography and etching methods, for instance, this conductive film on the second interlayer insulation film 31 will be patterned into metal wirings 37 and 39. Thus, the nonvolatile memory 1 according to this embodiment can be formed to have the layer structure as shown in FIG. 1.

As described above, in the method of manufacturing a nonvolatile memory according to the embodiment of the present invention, first, a semiconductor substrate 11 in which semiconductor elements such as transistors 10 are formed will be prepared. Next, an interlayer insulation film 21 (insulation film) will be formed on the semiconductor substrate 11. Next, a TiAlN film 32A (first film), which does not allow oxygen atoms to pass therethrough, will be formed on the interlayer insulation film 21. Next, a lower conductive film (first conductive film) including an Ir film 33A, an IrO₂ film 33B and a Pt film 33C will be formed on the TiAlN film 32A. Next, a ferroelectric film 34A (ferroelectric film) will be formed on the lower conductive film (33A, 33B and 33C). Next, an upper conductive film 35A (second conductive film), which is a Pt film, will be formed on the ferroelectric film 34A. Next, a laminated structure film (second film) made up of a TiN film 33D, a silicon oxide film 34B and a TiN film 35B, for instance, will be formed on the upper conductive film 35A. Next, the laminated structure film (33D, 34B and 35B) will be patterned into upper surface shapes of ferroelectric capacitors 30 to form multilayer structured hard masks (33E, 34C and 35C). Next, using the hard masks (33E, 34C and 35C) as masks, the upper conductive film 35A, the ferroelectric film 34A and the lower conductive film (33A, 33B and 33C) will be etched to form ferroelectric capacitors 30, each of which includes a lower electrode 33 (patterned first conductive film) made up of an Ir film 33a, an IrO₂ film 33b and a Pt film 33c, a capacity insulation film 34 (patterned ferroelectric film) and an upper electrode 35 (patterned second conductive film). Next, the TiAlN film 32A having been exposed by the etching of the upper electrode 35A, the ferroelectric film 34A and the lower conductive film (33A, 33B and 33C) will be etched using a mixed gas including a reductive gas.

In this way, in this embodiment, after the lower conductive film which is to become the lower electrodes 33 in the ferroelectric capacitors 30 is patterned, etching using a mixed gas including a reductive gas will be conducted. Thereby, in this embodiment, it is possible to raise the volatility of the conductive products adhered to the side faces of the capacity insulation films 34 at the time of patterning the lower conductive film. Accordingly, it is possible to remove the conductive products adhered to the side faces of the capacity insulation films 34 while etching the TiAlN film 32A. As a result, even when the upper conductive film 35A, the ferroelectric film 34A and the lower conductive film (33A, 33B and 33C) are etched continuously, i.e., even when these films are batch-processed, it will be possible to decrease possible leak current that can be generated between the upper electrode 35 and the lower electrode 33 in each ferroelectric capacitor 30.

While the preferred embodiments of the invention have been described using specific terms, such description is for illustrative purposes only, and it is to be understood that changes and variations may be made without departing from the spirit or the scope of the following claims.

This application claims priority to Japanese Patent Application No. 2006-32542. The entire disclosures of Japanese Patent Application No. 2006-32542 is hereby incorporated herein by reference.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing descriptions of the embodiments according to the present invention are provided for illustration only, and not for the purpose of limiting the invention as defined by the appended claims and their equivalents. Thus, the scope of the invention is not limited to the disclosed embodiments.

The term “configured” as used herein to describe a component, section or part of a device includes hardware and/or software that is constructed and/or programmed to carry out the desired function.

Moreover, terms that are expressed as “means-plus function” in the claims should include any structure that can be utilized to carry out the function of that part of the present invention.

The terms of degree such as “substantially,” “about,” and “approximately” as used herein mean a reasonable amount of deviation of the modified term such that the end result is not significantly changed. For example, these terms can be construed as including a deviation of at least ±5% of the modified term if this deviation would not negate the meaning of the word it modifies.

What is claimed is:

1. A method of manufacturing a ferroelectric capacitor, comprising:
preparing a substrate having an insulation film formed on a surface of the substrate;
forming a first film on the insulation film, the first film being a film which does not allow oxygen atoms to pass therethrough;
forming a first conductive film on the first film;
forming a ferroelectric film on the first conductive film;
forming a second conductive film on the ferroelectric film;
forming a second film on the second conductive film;
patterning the second film into a predetermined shape;
forming a ferroelectric capacitor by etching the second conductive film, the ferroelectric film and the first conductive film while using the patterned second film as a mask; and
etching the exposed first film by using a gas that comprises a reductive gas.

2. The method of manufacturing a ferroelectric capacitor according to claim 1, wherein
the first film is etched at a temperature below 80° C.

3. The method of manufacturing a ferroelectric capacitor according to claim 1, wherein
the reductive gas is a halide gas.

4. The method of manufacturing a ferroelectric capacitor according to claim 1, wherein
the reductive gas comprises at least one gas selected from the group consisting of BCl₃ gas, HBr gas and CHF₃ gas.

5. The method of manufacturing a ferroelectric capacitor according to claim 1, wherein
after the second conductive film, the ferroelectric film and the first conductive film are etched, a portion of the second film will remain on the patterned second conductive film.

6. A method of manufacturing a semiconductor memory device, comprising:
preparing a substrate having a semiconductor element;
forming an insulation film on a surface of the substrate;
forming a first film on the insulation film, the first film being a film which does not allow oxygen atoms to pass therethrough;
forming a first conductive film on the first film;
forming a ferroelectric film on the first conductive film;
forming a second conductive film on the ferroelectric film;
forming a second film on the second conductive film;
patterning the second film into a predetermined shape;
forming a ferroelectric capacitor by etching the second conductive film, the ferroelectric film and the first conductive film while using the patterned second film as a mask; and
etching the exposed first film using a mixed gas comprising a reductive gas.

7. The method of manufacturing a semiconductor memory device according to claim 6, wherein
the first film is etched at a temperature below 80° C.

8. The method of manufacturing a semiconductor memory device according to claim 6, wherein
the reductive gas is a halide gas.

9. The method of manufacturing a semiconductor memory device according to claim 6, wherein
the reductive gas comprises at least one gas selected from the group consisting of BCl₃ gas, HBr gas and CHF₃ gas.

10. The method of manufacturing a semiconductor memory device according to claim 6, wherein
the mixed gas comprising at least one gas selected from the group consisting of Ar gas and Cl₂ gas.

11. The method of manufacturing a semiconductor memory device according to claim 6, wherein
after the second conductive film, the ferroelectric film and the first conductive film are etched, a portion of the second film will remain on the patterned second conductive film.

12. The method of manufacturing a semiconductor memory device according to claim 6, wherein
the second film is a single or multiple layer film comprising a titanium nitride film or a titanium aluminum nitride film formed on the second conductive film.

13. The method of manufacturing a semiconductor memory device according to claim 6, wherein
the first film is a TiAlN film.

14. The method of manufacturing a semiconductor memory device according to claim 6, wherein
the first conductive film comprises
an iridium film formed on the first film,
an iridium oxide film formed on the iridium film, and
a platinum film formed on the iridium oxide film, and
the second conductive film includes a platinum film.

15. The method of manufacturing a semiconductor memory device according to claim 6, wherein
the ferroelectric film is a strontium bismuth tantalate film, a lead zirconate titanate film or a bismuth lanthanum titanate film.
